(19) United States
(12) Patent Application Publication
(10) Pub. No.: US 2007/0158843 A1
(43) Pub. Date: Jul. 12, 2007

(54) SEMICONDUCTOR PACKAGE HAVING IMPROVED SOLDER JOINT RELIABILITY AND METHOD OF FABRICATING THE SAME

(75) Inventors: Shin Kim, Chungcheongnam-do (KR); Se-Yong OH, Seoul (KR)

Correspondence Address: MARGER JOHNSON & MCCOLLOM, P.C., 210 SW MORRISON STREET, SUITE 400, PORTLAND, OR, 97204, US

(73) Assignee: SAMSUNG ELECTRONICS CO., LTD., Gyeonggi-do (KR)

(21) Appl. No.: 11/621,042

(22) Filed: Jan. 8, 2007

(30) Foreign Application Priority Data
Jan. 9, 2006 (KR) 2006-0002379

(51) Int. Cl. H01L 23/48

(52) U.S. Cl. 257/738

(57) ABSTRACT

A semiconductor package with improved solder joint reliability, and a method of fabricating the same are provided. The semiconductor package comprises a printed circuit board (PCB) having a plurality of interconnection layers formed on its surface, and having a plurality of through holes connected to the interconnection layers. An adhesive member is attached to an upper surface of the PCB, and a semiconductor chip is electrically connected to the interconnection layers and mounted on an upper surface of the adhesive member. A solder connecting part fills each through hole so as to form a mechanically strong connection that is resistant to breakage during thermal transients and physical impacts.

### CROSS-REFERENCE TO RELATED PATENT APPLICATION

This application claims the benefit of Korean Patent Application No. 10-2006-0002379, filed on Jan. 9, 2006, in the Korean Intellectual Property Office, the contents of which are herein incorporated by reference in their entirety.

### BACKGROUND

1. Field of the Invention

This disclosure relates to a semiconductor package and a method of fabricating the same, and more particularly, to a semiconductor package having improved thermal transient and mechanical impact characteristics leading to increased solder joint reliability, and a method of fabricating the same.

2. Description of the Related Art

Recent semiconductor packaging development efforts have been placing emphasis upon efficiently mounting various functional semiconductor chips and enabling high value-added packaging technology. Modern electronic devices have very demanding physical and thermal requirements. Modern semiconductor packaging development efforts typically focus on ways of minimizing the landscape utilized by each semiconductor package and improving the ability of the packages to withstand thermal transients and physical impact. As an example, the semiconductor packages on the motherboard of a mobile phone may be subjected to repeated thermal transients during periods of use and non-use and the packages may be subjected to physical impact as the phone is handled carelessly or dropped.

In order to meet the goal of decreasing electronic device size, external connection terminals of a semiconductor package have changed from a lead type to a solder ball type design in order to allow a larger number of external connection terminals to be placed within a limited area. Consequently, use of a ball grid array (BGA) package having the solder ball as an external connection terminal has been gradually increasing. The component of a BGA package that is most susceptible to failure caused by thermal transients and physical impact is the solder ball array. As described below, individual solder balls are susceptible to crack formation both within the solder balls and at the solder joint (i.e. the connection between a solder ball and a solder ball pad on a PCB). These cracks can lead to open electrical connections between the motherboard of the electronic device and the semiconductor chips mounted on the motherboard, which can result in failure of the entire electronic device.

FIG. 1 is a cross-sectional view illustrating a conventional semiconductor package using a printed circuit board.

Referring to FIG. 1, to manufacture a semiconductor package, an interconnection layer 56 is formed on a printed circuit board 50 to electrically connect with a solder ball 60 attached to the lower surface of the printed circuit board 50. One end of the interconnection layer 56 is connected to a bonding pad 57 in electrical contact with a bonding wire 53, and the other end of the interconnection layer 56 extends through a minute hole formed on the printed circuit board 50 and is connected to a solder ball pad 55 to which the solder ball 60, formed on the lower surface of the printed circuit board 50, is attached. A bonding pad plating layer 57a is formed on the surface of the bonding pad 57, and a solder ball pad plating layer 55a is formed on the surface of the solder ball pad 55.

On the upper surface and lower surface of the printed circuit board 50 where the bonding pad 57, the solder ball pad 55 and the interconnection layer 56 are formed, an upper surface photo solder resist (PSR) layer 51b and a lower surface PSR layer 51a are formed, respectively. The upper surface PSR layer 51b and the lower surface PSR layer 51a expose the bonding pad plating layer 57a on the bonding pad 57 and the solder ball pad plating layer 55a on the solder ball pad 55, respectively, and insulate adjacent solder balls 60 from each other.

An adhesive member 54 is formed on the upper surface PSR layer 57a, a semiconductor chip 52 is mounted on the adhesive member 54, and an encapsulating resin 58 is formed, sealing the upper surface of the printed circuit board 50, on which the semiconductor chip 52 is mounted.

The solder ball plating layer 55a is formed including, for example, a nickel (Ni) plating layer and a gold (Au) plating layer on the surface of the solder ball pad 55 formed and exposed on the lower surface of the printed circuit board 50. When the solder ball 60 is attached to the solder ball plating layer 55a in a subsequent process, a brittle inter metallic compound layer such as nickel-tin (Ni—Sn) or nickel-copper-tin (Ni—Cu—Sn) is formed at a bonding interface between the solder ball 60 and the solder ball pad 55. The inter metallic compound layer causes problems in that the brittle inter metallic layer is likely to be easily separated and broken. This problem is exacerbated in semiconductor packages having solder balls that are exposed to repeated thermal transients and physical impact, such as in mobile phone applications. As described above, the failure of a single solder joint due to the inter metallic compound layer can cause the failure of an entire electronic device.

Consequently, there is a need for a semiconductor package having improved resistance to thermal transients and physical impact through increased solder joint reliability.

### SUMMARY

The present invention provides an improved semiconductor package in which an inter metallic compound layer between a solder ball and a solder ball pad is strengthened such that thermal transient and mechanical impact characteristics are improved for the overall package.

The present invention also provides an improved stack-type semiconductor package in which an inter metallic compound layer between a solder ball and a solder ball pad is strengthened such that thermal transient and mechanical impact characteristics are improved for the stacked package.

The present invention also provides a method of fabricating an improved semiconductor package and an improved stack-type semiconductor package.

### BRIEF DESCRIPTION OF THE DRAWINGS

The above and other features and advantages of the present invention will become more apparent by describing in detail exemplary embodiments thereof with reference to the attached drawings in which:

FIG. 1 is a cross-sectional view illustrating a conventional semiconductor package using a printed circuit board;

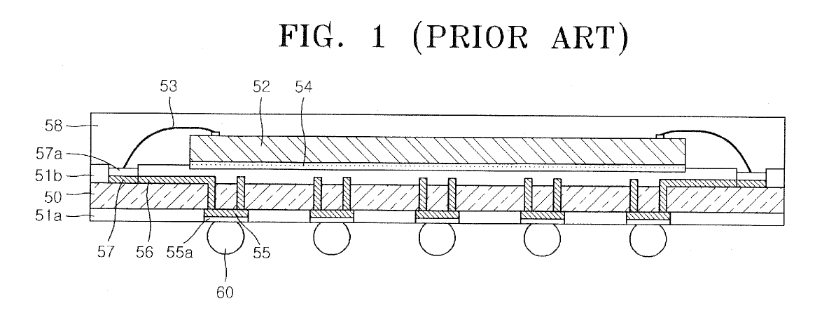

FIG. 2 is a cross-sectional view illustrating a semiconductor package using a printed circuit board (PCB) according to an embodiment of the present invention;

FIG. 3 is an enlarged cross-sectional view illustrating a portion A of FIG. 2;

FIGS. 4 and 5 are a cross-sectional view and a plan view illustrating a PCB according to an embodiment of the present invention;

FIGS. 6 and 7 are a cross-sectional view and a plan view illustrating a photo solder resist (PSR) formed on an upper surface and a lower surface of the PCB of FIGS. 4 and 5;

FIGS. 8 and 9 are a cross-sectional view and a plan view illustrating an adhesive member of the semiconductor package formed on the upper surface of the PCB of FIGS. 6 and 7; and

FIG. 10 is a cross-sectional view illustrating a stack-type semiconductor package according to an embodiment of the present invention.

### DETAILED DESCRIPTION OF EXAMPLE EMBODIMENTS

The present invention will now be described more fully hereinafter with reference to the accompanying drawings, in which preferred embodiments of the invention are shown. This invention may, however, be embodied in many different forms and should not be construed as being limited to the embodiments set forth herein. Rather, these embodiments are provided so that this disclosure will be thorough and complete, and will fully convey the scope of the disclosure to those skilled in the art.

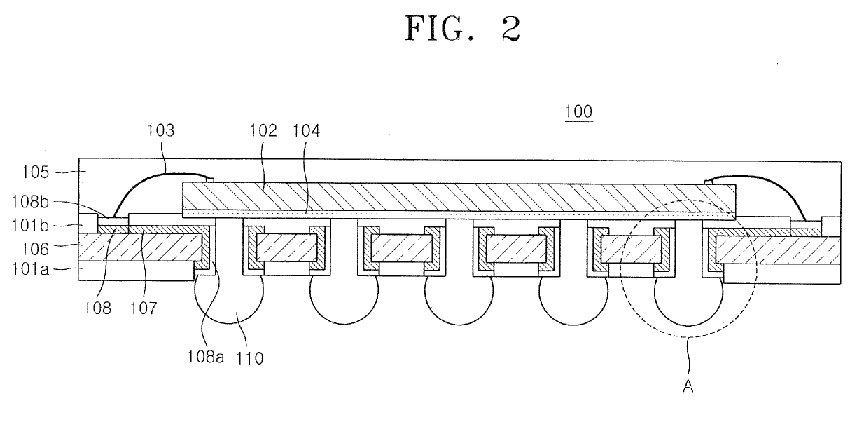

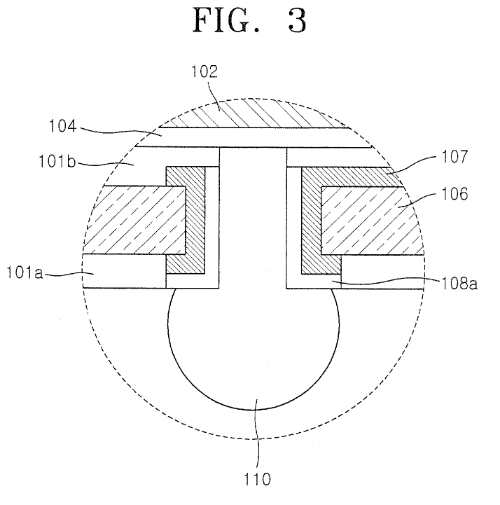

FIG. 2 is a cross-sectional view illustrating a semiconductor package according to an embodiment of the present invention, and FIG. 3 is an enlarged cross-sectional view illustrating a portion A of FIG. 2.

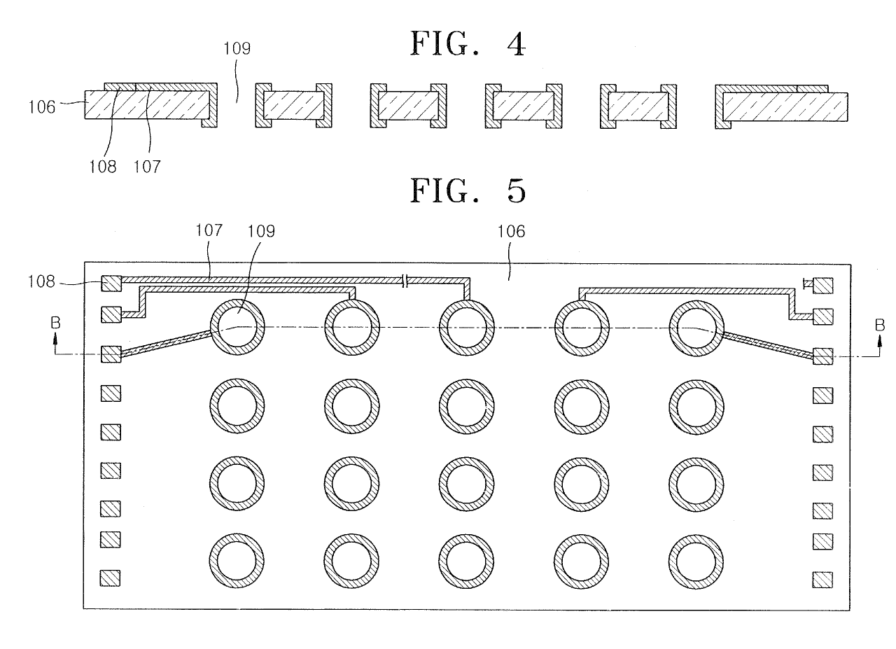

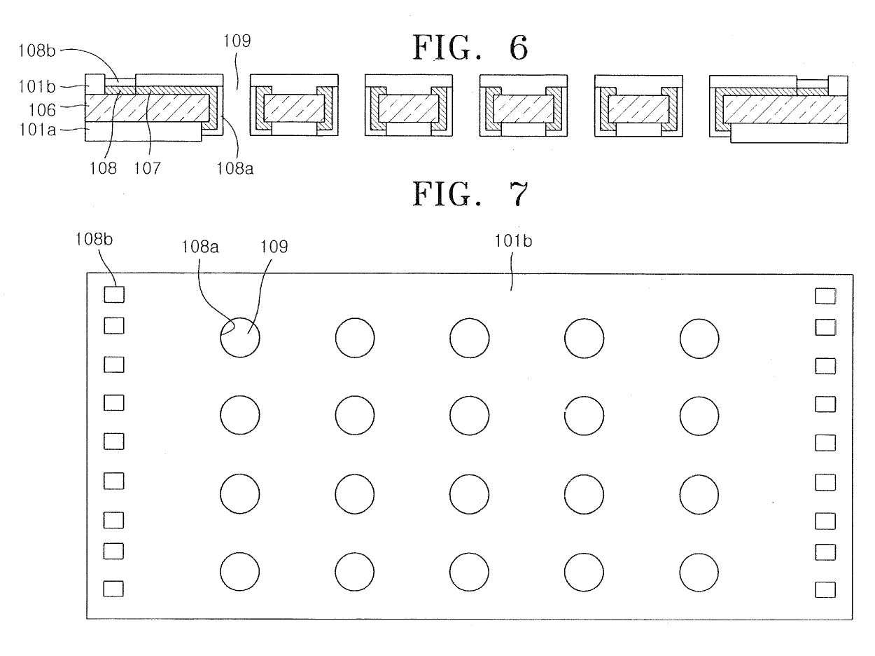

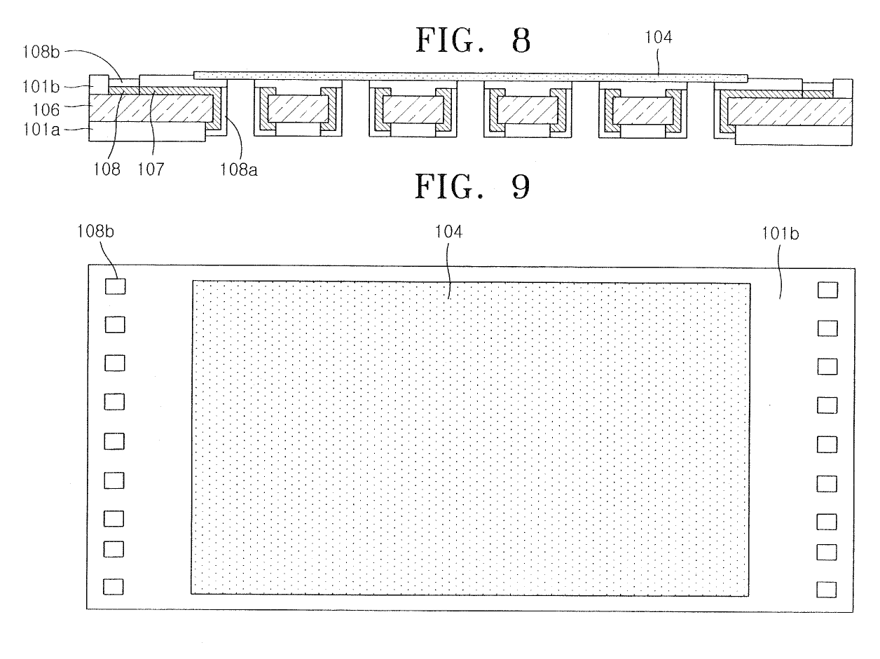

FIGS. 4 and 5 are a cross-sectional view and a plan view illustrating the PCB of FIG. 2, and FIGS. 6 and 7 are a cross-sectional view and a plan view illustrating a photo solder resist ( ) formed on an upper surface and a lower surface of the PCB of FIGS. 4 and 5. FIGS. 8 and 9 are a cross-sectional view and a plan view illustrating an adhesive member of the semiconductor package formed on the upper surface of the PCB of FIGS. 6 and 7.

Referring to FIG. 2, a semiconductor package 100 according to an embodiment of the present invention is formed such that a semiconductor chip 102, mounted on a printed circuit board (PCB) 106, is electrically connected to an interconnection layer 107 of the PCB 106 through a bonding wire 103. The semiconductor chip 102 is electrically connected to external circuits by, for example, a solder connecting part 10 in electrical contact with the interconnection layer 107. A part of the PCB 106, the semiconductor chip 102 and the bonding wire 103 are encapsulated by a known encapsulant such as an epoxy mold compound (EMC) 105.

Referring to FIGS. 2, 4 and 5, the PCB 106 comprises a plurality of through holes 109 extending therethrough. Further, a plurality of interconnection layers 107 are disposed on the upper surface of the PCB 106, and one end of each interconnection layer 107 is connected to a bonding pad 108. The other end of each interconnection layer 107 is connected to the through hole 109. The interconnection layer 107 may be formed in a donut shape surrounding the edge of the through hole 109, covers the inner wall of the through hole 109, and is formed also in a donut shape on the opposite lower surface of the PCB 106 around the edge of the through hole 109. FIG. 5 illustrates only some of the through holes 109, but more through holes 109 may be formed in accordance with various array patterns known in the art of semiconductor packaging. One through hole 109 may be connected to each bonding pad 108, but dummy through holes, not connected to bonding pads, may be further formed if necessary. The PCB 106 may include a flexible substrate made of a polymide or similar flexible material, or a rigid substrate made of FR4 resin or similar rigid material.

Referring to FIGS. 2, 3, 6 and 7, an upper PSR layer 101b and a lower PSR layer 101a, which are formed of an insulating material, are disposed on the upper surface and the lower surface of the PCB 106 on which the interconnection layer 107 is formed. The upper PSR layer 101b and the lower PSR layer 101a are disposed to expose the through holes 109. Further, a portion of the upper PSR layer 101b on the bonding pad 108 is removed to expose the bonding pad 108, and also exposes a portion of the donut-shaped interconnection layer 107 extending to the lower surface of the PCB 106. As well illustrated in FIG. 3, this approach is preferable to the prior art approach in that the contact area between the interconnection layer 107 and the solder connecting part 110, to be formed during a subsequent process, can be enlarged so as to improve the solder joint reliability. In the meantime, a bonding pad plating layer 108b and an interconnection layer plating layer 108a are disposed on the exposed surface of the exposed bonding pad 108, which is not covered by the upper PSR layer 101b and the lower PSR layer 101a, and the exposed surface of the donut-shaped interconnection layer 107 covering the inner wall of the through hole 109 and extending to the lower surface of the PCB 106.

The bonding pad plating layer 108b and the interconnection layer plating layer 108a may be formed by plating a metal selected from the group consisting of Cu, Ni, Au, Ag, Pt. Pd. and alloys thereof. For example, the plating layers 108a and 108b may be formed by stacking Ni with a thickness of about 0.5 μm or higher and Au with a thickness of about 0.3 μm or higher on the Ni. However, the bonding pad plating layer 108b and the interconnection layer plating layer 108a may be formed by other suitable known methods other than plating.

Including Au in the plating layers 108a and 108b improves wetting at the interface contacting the solder connecting part 110, and as the thickness of Au of the plating layers 108a and 108b is increased, the mechanical strength with the solder connecting part 110 is increased, thereby improving the solder joint reliability. Au of the plating layers 108a and 108b is also stable against heat applied to the PCB 106. Further, the surface of the plating layers 108a and 108b, which easily react with oxygen, may be processed with an OSP (organic solderability preservative) process to prevent oxidation.

Referring to FIGS. 2, 8, and 9, an adhesive member 104 is attached to a portion of the PCB 106 on which the upper PSR layer 101b is formed. The adhesive member 104 is attached to cover the upper surfaces of the through holes 109 and close them off. The adhesive member 104 may use polyimide resin having an adhesive (not shown) coated on both of its surfaces. The adhesive may use one of thermo-setting resin, thermo-plastic resin, or other suitable adhesive materials within the spirit and scope of the invention.

Referring to FIG. 2 again, a semiconductor chip 102 may be mounted on the adhesive member 104, and the pads disposed along the upper surface edge of the semiconductor chip 102 and the bonding pad 108 of the PCB 106 are electrically connected via the bonding wire 103. The structure may be encapsulated by an EMC encapsulating resin 105 or other suitable encapsulants known to one skilled in the art. Further, the solder connecting part 110 such as a solder ball or a solder bump is formed to fill the through hole 109 during a subsequent reflow process. The solder connecting part 110 may include Sn as a main material, and may further include Pb, Ni, Ag, Cu, Bi, or alloys thereof. The solder connecting part 110 also may include a Pb-free solder. The solder connecting parts 110 are electrically connected through the plating layer 108a of the through hole 109 to the interconnection layer 107, and are electrically isolated from each other by a lower surface PSR layer 101a as an insulating material.

Referring to FIG. 3, since the area of the solder connecting part 110 filled inside the through hole 109 in contact with the plating layer 108a of the PCB 106 is increased, thermal stress focused on the solder joint is dispersed, and thus, thermal transient and mechanical impact characteristics are improved. An inter metallic compound layer at an interface of the solder connecting part 110 and the plating layer 108a is a brittle portion, which may be easily broken when a thermal transient or mechanical impact is applied to the semiconductor package. The inter metallic compound layer is formed of a relatively hard and easily brittle material as compared to the solder connecting part 110. Since the solder connecting part 110 has a low hardness, it can absorb impact relatively well compared to the rigid inter metallic compound layer.

Referring to FIGS. 2 through 9, a method of fabricating a semiconductor package according to an embodiment of the present invention will be explained.

Referring to FIGS. 4 and 5, a PCB 106 is formed. The PCB 106 includes a plurality of bonding pads 108 for electrical connection to a semiconductor chip 102, a plurality of interconnection layers 107, and a plurality of through holes 109.

The through holes 109 may be formed using a drilling and/or laser operation, or other methods known in the art of semiconductor packaging. An interconnection layer 107 connects a bonding pad 108 and a through hole 109. The interconnection layer 107 is formed in a donut shape along the inner wall and the edge of the through hole 109. The through hole 109 is formed at the position where the solder connecting part 110 will be formed. The solder connecting part 110 will fill the through hole 109, so as to further increase the solder joint reliability. The size and depth of the through hole 109 are critical parameters in order to achieve the objects of the present invention. For example, the width of the through holes 109 may be larger than about half the diameter of a solder ball formed as part of the solder connecting part. Also, the width of the through holes 109 may be approximately equal to the diameter of a solder ball or solder bump formed as part of the solder connecting part. The depth of the through holes 109 may be substantially equal to the thickness of the PCB 106. One of ordinary skill in the art will appreciate that an optimum solder joint reliability may be obtained by varying the width and the depth of the through holes 109.

Referring to FIGS. 6 and 7, an upper surface PSR layer 101b and a lower surface PSR layer 101a are respectively formed on the upper surface and the lower surface of the PCB 106 on which the interconnection layer 107 is formed. Portions of the upper surface PSR layer 101b and the lower surface PSR layer 101a corresponding to the positions where the through holes 109 exist are opened. In other words, the PSR layers 101a and 101b may not cover the through holes 109. However, according to some embodiments, it is possible for the upper surface PSR layer 101b to cover the top of the through holes 109. In this case, the upper PSR layer 101b will form the upper surface of the through holes 109. Next, on the exposed surfaces of the bonding pad 108 and the interconnection layer 107 exposed from the upper surface PSR layer 101b and the lower surface PSR layer 101a, plating layers 108a and 108b are formed using electro-plating, electroless plating, and/or other processes known in the art.

Referring to FIGS. 8 and 9, an adhesive member 104 is formed on the upper PSR layer 101b to cover the plurality of through holes 109. If the through holes 109 were exposed by the upper PSR layer 101b , as described above, then the adhesive member 104 will form the upper surface of the through holes 109. The adhesive member 104 may use a liquid-type or a sheet-type material, and in this embodiment, uses polyimide resin. The adhesive member 104 may function as a stopping layer when the solder connecting part 110 fills the through hole 109 during a subsequent process.

Then, as illustrated in FIG. 2, a semiconductor chip 102 is mounted on the adhesive member 104 using a typical method, and a wire bonding process is performed. Then, an encapsulating process is performed using an EMC 105, thereby encapsulating the bonding wires 103 and the top surface of the semiconductor chip 102. Finally, the solder connecting part 110 is formed so as to fill and extend beyond the through hole 109 thereby forming external electrical connections and completing the semiconductor package.

The solder connecting parts 110 may be formed by several methods. For instance, a single process may be used to form both the portion of the solder connecting part 110 inside of the through hole 109 and the portion extending beyond the through hole. Alternatively, separate processes may be used to form the portion inside the through hole and the portion outside the through hole. These processes may include printing of solder paste onto the PCB and then reflowing the solder paste to fill the through holes and form the portion of the solder connecting part 110 that extends outside the through hole 109. As a further example, solder paste may be printed into the through holes 109, and then a subsequent solder printing, or other process, may be used to place more solder paste or solder balls onto the first solder paste. In this case, both portions of the solder connecting part may be reflowed simultaneously.

Normally, the semiconductor package is mounted on a mother board of an electronic product, and operates in conjunction with other components on the mother board. However, the spirit of the present invention can be more broadly applied to a PCB on which the semiconductor package is mounted. That is, a plurality of through holes may be formed through the mother board used in a mobile electronic product, and an adhesive member may be attached to the upper surface thereof, in accordance with the embodiments described above.

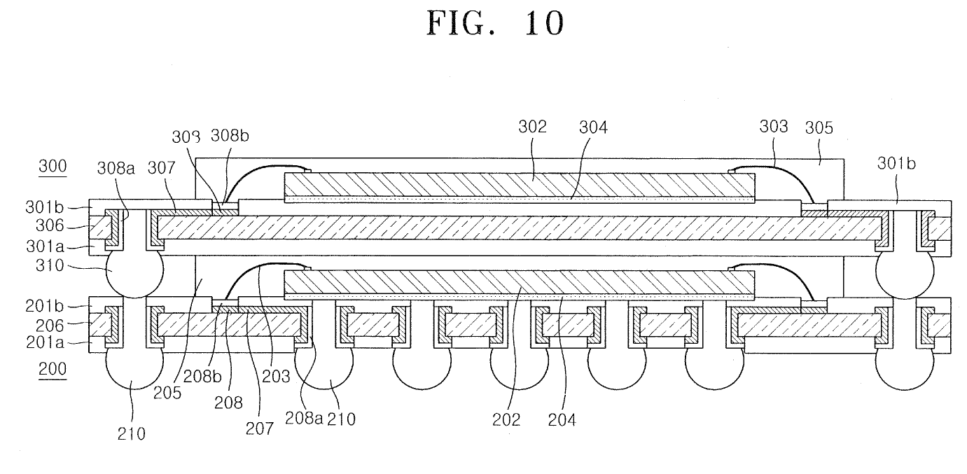

FIG. 10 is a cross-sectional view illustrating a stack-type semiconductor package according to an embodiment of the present invention.

Referring to FIG. 10, a first semiconductor package 200 disposed at a lower position and a second semiconductor package 300 disposed at an upper position are coupled with a stack-type connection arrangement. Another semiconductor package may be further stacked on the second semiconductor package 300.

The first semiconductor package 200 is similar to the semiconductor package 100 of FIG. 2 as described above, but through holes are additionally formed along the outer edge of a first PCB 206. The additional through holes are formed corresponding to the positions where second solder connecting parts 310 formed in a second semiconductor package 300 will be formed. In the additional through holes, an interconnection layer 207 is also formed in a donut shape along the inner wall and the edge of the through hole, and a plating layer 208a is formed on the exposed surface of the interconnection layer 207. An upper surface PSR layer 201b and a lower surface PSR layer 201a are respectively formed on the upper surface and the lower surface of the first PCB 206. A first adhesive member 204 is formed on the upper surface PSR layer 201b, and a first semiconductor chip 202 is mounted on the first adhesive member 204. The first semiconductor chip 202 and a first bonding pad 208 are electrically connected by a first bonding wire 203, and are encapsulated by a first EMC 205.

A second semiconductor package 300 is formed in such a manner that the second through holes and the second solder connecting part 310 are not disposed at its center portion, unlike the first semiconductor package 200, to facilitate easy stacking. The second through holes and the solder connecting part 310 are formed along the edge of the second semiconductor package 300 at the positions corresponding to the additional through holes of the first semiconductor package 200. The donut-shaped interconnection layer 307 is formed along the inner wall and the edge of the second through hole. An upper surface PSR layer 301b and a lower surface PSR layer 301a are formed on the upper surface and the lower surface of the second PCB 306. A plating layer 308a is formed on the exposed surface of the interconnection layer 307. A second adhesive member 304 is formed on the upper PSR layer 301b, a second semiconductor chip 302 is mounted on the second adhesive member 304, and the second semiconductor chip 302 and the second bonding pad 308 are electrically connected by the second bonding wire 303, and are encapsulated by an EMC 305.

In this embodiment, the lower PSR layer 301 a of the second semiconductor package and the EMC 205 of the first semiconductor package 200 are formed in contact with each other, but this does not necessarily have to be the case, as there may be an air gap between the lower PSR layer 301a and the EMC 205. The present invention can be applied in the case of stacking a plurality of semiconductor chips on a single PCB, and can also applied to a BGA package in various shapes using a solder connecting part as an exterior connecting terminal.

According to an aspect of the present invention, there is provided a semiconductor package comprising a printed circuit board (PCB) having a plurality of interconnection layers formed on its surface, and having a plurality of through holes connected to the interconnection layers respectively. An adhesive member is attached to an upper surface of the PCB, and a semiconductor chip is electrically connected to the interconnection layers of the PCB, and mounted on an upper surface of the adhesive member. A solder connecting part fills each through hole.

Further, photo solder resist (PSR) layers may be formed on an upper surface and a lower surface of the PCB, and the PSR layer in the through holes of the PCB is removed. Also, in the PCB, one end of the interconnection layer may be connected to a bonding pad, and the other end of the interconnection layer may be formed in a donut-shape along the edge of the through hole, and may extend to or cover an inner wall of the through hole. The interconnection layer may extend along the inner wall of the through hole, and may be formed in a donut-shape along the edge of the through hole on the lower surface of the PCB.

A plating layer may be further formed on the inner wall of the through hole and on an exposed portion of the interconnection layer formed on the lower surface of the PCB. The solder connecting part may be a solder ball or a solder bump, and the adhesive member may be formed of a film-type resin. The semiconductor package may further comprise an epoxy mold compound (EMC) encapsulating the semiconductor chip and a portion of the PCB.

According to another aspect of the present invention, there is provided a stack-type semiconductor package comprising a first semiconductor package; and a second semiconductor package stacked on the first semiconductor package.

The first semiconductor package comprises a first PCB having a plurality of edge through holes formed in an edge of the first PCB; and a plurality of central through holes formed in the center portion of the first semiconductor package, and connected to a plurality of first interconnection layers; a first adhesive member covering the central through holes and attached to an upper surface of the first PCB; a first semiconductor chip being electrically connected to the first interconnection layers of the first PCB and mounted on an upper surface of the first adhesive member; first solder connecting parts filling the central and edge through holes; and a first EMC encapsulating the semiconductor chip and a portion of the PCB.

The second semiconductor package comprises a second PCB connected to the interconnection layers, and having a plurality of edge through holes formed on an edge of the second PCB corresponding to the edge through holes of the first semiconductor package; a second adhesive member attached to an upper surface of the second PCB; a second semiconductor chip electrically connected to the interconnection layers of the second PCB, and mounted on an upper surface of the second adhesive member; second solder connecting parts filling the edge through holes of the second PCB, and electrically connected to the first solder connecting parts filling the edge through holes of the first PCB; and a second EMC encapsulating the second semiconductor chip and a portion of the second PCB.

According to another aspect of the present invention, there is provided a method of fabricating a semiconductor package comprising forming a PCB having a plurality of interconnection layers respectively connected to bonding pads at each end, and having a plurality of through holes respectively connected to the interconnection layers. Then, after a photo solder resist (PSR) layer is formed on an upper surface of the PCB, an adhesive member is attached to an upper surface of the PSR layer; and a semiconductor chip is mounted on an upper surface of the adhesive member, and the semiconductor chip and the bonding pads are wire-bonded. Then, the through holes are filled with solder connecting parts.

In the forming of the PSR layer, the PSR layer may be formed such that portions where the through holes are formed are exposed, and in the forming of the PSR layer, a PSR layer may be formed on a lower surface of the PCB.

Further, before the wire-bonding, the method may further comprise forming a plating layer on the inner walls of the bonding pad and the through hole, and on the interconnection layer exposed on the lower surface of the PCB, and after filling with the solder connecting part, the method may further comprise encapsulating the semiconductor chip and a portion of the PCB.

According to some embodiments of the present invention, the thermal transient and mechanical impact characteristics can be greatly improved for various types of BGA packages using a solder ball as an external connecting terminal by controlling the size of a through hole of the PCB, and using a surface plating layer and an adhesive member attached to the PCB. Furthermore, the thermal transient and mechanical impact characteristics of a semiconductor package attached to a mother board of an electronic device such as a mobile phone can be dramatically improved.

While the present invention has been particularly shown and described with reference to exemplary embodiments thereof, it will be understood by those of ordinary skill in the art that various changes in form and details may be made therein without departing from the spirit and scope of the present invention as defined by the following claims.

What is claimed is:

1. A semiconductor package comprising:
a printed circuit board (PCB) having at least one interconnection layer formed on its surface, and having at least one through hole connected to the interconnection layer;
an adhesive member attached to an upper surface of the PCB;
a semiconductor chip electrically connected to the at least one interconnection layer of the PCB and mounted on an upper surface of the adhesive member; and
a solder connecting part disposed to fill each through hole.

2. The semiconductor package of claim 1, wherein photo solder resist (PSR) layers are formed on the upper surface and a lower surface of the PCB.

3. The semiconductor package of claim 2, wherein the PRS layer on the lower surface of the PCB isolates adjacent solder connecting parts from each other.

4. The semiconductor package of claim 2, wherein the PSR layer in each of the through holes of the PCB is removed.

5. The semiconductor package of claim 1, wherein the solder connecting parts comprise a lead-free solder material.

6. The semiconductor package of claim 1, wherein one end of at least one of the interconnection layers is connected to a bonding pad, and the other end of the at least one interconnection layer is formed in a donut-shape along the edge of at least one of the through holes.

7. The semiconductor package of claim 6, wherein the at least one interconnection layer extends along the inner wall of the at least one through hole and is formed in a donut-shape along the edge of the through hole on a lower surface of the PCB.

8. The semiconductor package of claim 7, further comprising a plating layer formed on the inner wall of the through hole and on an exposed portion of the at least one interconnection layer formed on the lower surface of the PCB.

9. The semiconductor package of claim 8, wherein the plating layer comprises a layer of nickel and a layer of gold.

10. The semiconductor package of claim 6, further comprising a bond pad plating layer formed on a portion of the bonding pad not covered by the PSR layer.

11. The semiconductor package of claim 1, wherein the solder connecting part contacts a bottom surface of the adhesive member.

12. The semiconductor package of claim 1, wherein the solder connecting part extends below the through hole and comprises a solder ball or a solder bump.

13. The semiconductor package of claim 12, wherein the width of the through hole is greater than about half of the diameter of the solder ball or solder bump.

14. The semiconductor package of claim 12, wherein the width of the through hole is approximately equal to the diameter of the solder ball or solder bump.

15. The semiconductor package of claim 1, wherein the adhesive member is a film-type resin.

16. The semiconductor package of claim 15, wherein the adhesive member comprises an upper adhesive layer and a lower adhesive layer.

17. The semiconductor package of claim 16, wherein the upper adhesive layer and the lower adhesive layer comprise one of a thermo-setting resin and a thermo-plastic resin.

18. The semiconductor package of claim 1, wherein the PCB comprises a mother board for a mobile phone.

19. The semiconductor package of claim 1, further comprising an epoxy mold compound (EMC) encapsulating the semiconductor chip and a portion of the PCB.

20. The semiconductor package of claim 1, wherein the PCB is a flexible substrate.

21. The semiconductor package of claim 1, further comprising at least one dummy through hole that is not connected to an interconnection layer.

22. The semiconductor package of claim 1, wherein the depth of the through holes is substantially equal to the thickness of the PCB.

23. A stack-type semiconductor package comprising:
a first semiconductor package; and
a second semiconductor package stacked on the first semiconductor package,
wherein the first semiconductor package comprises:
a first PCB having a plurality of edge through holes formed on an edge portion of the first PCB and a plurality of central through holes formed in the center portion of the first PCB, and the central through holes connected to a plurality of first interconnection layers;
a first adhesive member covering the central through holes and attached to an upper surface of the first PCB;
a first semiconductor chip being electrically connected to the first interconnection layers of the first PCB and mounted on an upper surface of the first adhesive member;
first solder connecting parts filling the central and edge through holes; and
a first epoxy mold compound (EMC) encapsulating the semiconductor chip and a portion of the first PCB,
and wherein the second semiconductor package comprises:
a second PCB having a plurality of edge through holes formed on an edge portion of the second PCB corresponding to the edge through holes of the first semiconductor package and connected to a plurality of second interconnection layers;
a second adhesive member attached to an upper surface of the second PCB;
a second semiconductor chip electrically connected to the second interconnection layers of the second PCB, and mounted on an upper surface of the second adhesive member;
second solder connecting parts filling the edge through holes of the second PCB, and electrically connected to the first solder connecting parts filling the edge through holes of the first PCB; and
a second EMC encapsulating the second semiconductor chip and a portion of the second PCB.

24. The semiconductor package of claim 23, further comprising photo solder resist (PSR) layers formed on an upper surface and a lower surface of the first and second PCBs.

25. The semiconductor package of claim 23, further comprising one or more additional semiconductor packages stacked on the second semiconductor package.

26. A method of fabricating a semiconductor package comprising:
forming a printed circuit board (PCB);
forming a plurality of bonding pads on the PCB;
forming a plurality of through holes penetrating the PCB;
forming a plurality of interconnection layers, wherein one end of at least one of the interconnection layers is connected to at least one of the bonding pads and the other end of the at least one interconnection layer is connected to at least one of the through holes;
forming a photo solder resist (PSR) layer on an upper surface of the PCB;
attaching an adhesive member on an upper surface of the PSR layer;
mounting a semiconductor chip on an upper surface of the adhesive member;
wire-bonding between the semiconductor chip and the bonding pads; and
filling the plurality of through holes with a plurality of solder connecting parts.

27. The method of claim 26, wherein the PSR layer is formed such that portions where the through holes are formed are exposed.

28. The method of claim 26, wherein the end of the interconnection layer that is connected to the through hole is formed in a donut shape along the edge of the through hole, extends to the inner wall of the through hole, and is formed in a donut shape along the edge of the through hole on a lower surface of the PCB.

29. The method of claim 26, wherein the PSR layer is also formed on a lower surface of the PCB.

30. The method of claim 18, further comprising forming a plating layer on the inner walls of the bonding pad and the through hole, and on the interconnection layer exposed on the lower surface of the PCB.

31. The method of claim 30, wherein forming the plating layer comprises one of an electroplating process and an electroless process.

32. The method of claim 26, further comprising encapsulating the semiconductor chip and a portion of the PCB after filling with the plurality of solder connecting parts.

33. The method of claim 26, wherein filling the plurality of through holes comprises:
printing solder paste into the through holes; and
heating the solder paste to cause the solder paste to reflow.

34. The method of claim 26, wherein forming the plurality of through holes comprises one of a drilling and laser operation.

35. The method of claim 26, wherein attaching the adhesive member comprises one of a sheet-type adhesive and a liquid-type adhesive.

36. The method of claim 26, wherein the adhesive member forms the upper surface of the through holes prior to filling the through holes.

37. The method of claim 26, wherein the PSR layer forms the upper surface of the through holes prior to filling the through holes.

38. A method of fabricating a stacked package comprising:
forming a first printed circuit board (PCB) and a second PCB;
forming a plurality of first bonding pads on the first PCB and a plurality of second bonding pads on the second PCB;
forming a plurality of first edge through holes penetrating the first PCB at an edge portion and a plurality of center through holes penetrating the first PCB at a center portion;
forming a plurality of second edge through holes penetrating the second PCB and corresponding to the first edge through holes;
forming a plurality of first interconnection layers, wherein one end of at least one of the first interconnection layers is connected to at least one of the first bonding pads and the other end of the at least one first interconnection layer is connected to at least one of the center through holes;
forming a plurality of second interconnection layers, wherein one end of at least one of the second interconnection layers is connected to at least one of the second bonding pads and the other end of the at least one second interconnection layer is connected to at least one of the second edge through holes;
forming a first photo solder resist (PSR) layer on an upper surface of the first PCB and a second PSR layer on an upper surface of the second PCB;
attaching a first adhesive member on an upper surface of the first PSR layer and a second adhesive member on an upper surface of the second PSR layer;
mounting a first semiconductor chip on an upper surface of the first adhesive member and a second semiconductor chip on an upper surface of the second adhesive member;
electrically connecting the first semiconductor chip and the first bonding pads;
electrically connecting the second semiconductor chip and the second bonding pads;
filling the plurality of first edge through holes with a plurality of first edge solder connecting parts;
filling the plurality of center through holes with a plurality of center connecting parts; and
filling the plurality of second edge through holes with a plurality of second edge solder connecting parts, so as to electrically connect the first edge through holes with the second edge through holes.

39. The method of claim 38, wherein the first PCB comprises a motherboard of a mobile phone.

40. A semiconductor package comprising:
a printed circuit board (PCB) having at least one interconnection layer formed on its surface, and having at least one through hole connected to the interconnection layer;
a semiconductor chip electrically connected to the at least one interconnection layer of the PCB; and
a solder connecting part disposed to fill each through hole.
